(19) United States
(12) Patent Application Publication
(10) Pub. No.: US 2021/0126022 A1
(43) Pub. Date: Apr. 29, 2021

(54) ARRAY SUBSTRATE AND METHOD FOR MANUFACTURING SAME

(71) Applicant: Wuhan China Star Optoelectronics Technology Co., Ltd., Wuhan, Hubei (CN)

(72) Inventor: Chengzhi LUO, Wuhan, Hubei (CN)

(21) Appl. No.: 16/772,834

(22) PCT Filed: Nov. 12, 2019
(86) PCT No.: PCT/CN2019/117648

§ 371 Date: Jun. 15, 2020

(30) Foreign Application Priority Data
Aug. 26, 2019 (CN) 201910788560.0

(51) Int. Cl. H01L 27/12; H01L 29/786; H01L 29/66; G02F 1/1368

(52) U.S. Cl. CPC H01L 27/1251; H01L 27/1218; H01L 27/1225; H01L 27/124; H01L 29/78603; H01L 29/78675; G02F 1/1368; H01L 27/1262; H01L 27/1274; H01L 27/1288; H01L 29/66757; H01L 29/66969; H01L 29/7869

(57) ABSTRACT

The present disclosure provides an array substrate and a method for manufacturing the same. By disposing hybrid TFT on the substrate which includes disposing an oxide TFT in a display driving area and disposing an LTPS TFT in a non-display driving area, not only can a driving current of an LCD gate driving circuit be improved, but a leakage current can also be diminished when LCD display pixels are driven. When manufacturing a hybrid TFT structure, a second active layer in the display driving area is disposed on a first active layer, and a semiconductor insulation layer is disposed between the first active layer and the second active layer, so that patterns of the first active layer and the second active layer can be formed by etching through one mask during an etching process, thus reducing manufacturing cost.

### TECHNICAL FIELD

The present disclosure relates to the display technology field, and in particular, to an array substrate and a method for manufacturing the same.

### BACKGROUND

Along with development of display technology, flat panel display devices such as liquid crystal displays (LCDs) have advantages including high-definition, power saving, thin body, and wide application range, and therefore are widely used in mobile phones, televisions, personal digital assistants, digital cameras, laptops, desktop computers, and other consumer electronic products, becoming a mainstream of display devices.

Thin film transistors (TFTs) are main driving elements in an LCD display device, and are directly related to a development direction of high performance flat display devices. The TFTs used in the display device need to consider various factors such as uniformity, leakage current, effective driving length, area efficiency, and hysteresis effect. According to different active layer materials, TFTs are classified into amorphous silicon (a-si) TFTs, low temperature poly-silicon (LTPS) TFTs, and metal oxide TFTs. Among them, LTPS TFTs have advantages of high mobility, small size, fast charging and fast switching speed, etc., and have a good effect when used for gate driving. Meanwhile, metal oxide TFTs have advantages of good uniformity and low leakage current, and can be used for display pixel driving. Therefore, hybrid TFTs comprising LTPS TFTs for gate driving and metal oxide TFTs for display pixel driving can be manufactured, which can not only increase a driving current in an LCD gate driving circuit, but also reduce a leakage current when LCD display pixels are driven.

Commonly used hybrid TFTs comprise an LTPS TFT and an indium gallium zinc oxide (IGZO) TFT. As shown in FIG. 1 and FIG. 2, two hybrid TFTs with different structures are illustrated. Wherein in FIG. 1, a low temperature polysilicon 11 and a metal oxide 12 are located in a same plane and the hybrid TFT has a top-gate structure, while in FIG. 2, a low temperature polysilicon 11a and a metal oxide 12a are located in different planes and the hybrid TFT has a bottom-gate structure. During manufacturing of the structures as shown in FIG. 1 and FIG. 2, when manufacturing the hybrid TFT comprising the LTPS TFT and the IGZO TFT, an additional mask used to form an IGZO active layer pattern is needed on the basis of original cost, therefore increasing process complexity and cost.

### SUMMARY

Therefore, an array substrate and a method for manufacturing the same are provided to effectively reduce a number of masks during a hybrid TFT process, thus reducing the cost.

The technical problem can be solved by the present disclosure providing an array substrate and a method for manufacturing the same. When manufacturing a hybrid TFT, a second active layer in the display driving area is disposed on a first active layer and a semiconductor insulation layer is disposed between the first active layer and the second active layer to form patterns of the first active layer and the second active layer by etching through one mask, thus reducing the cost.

To solve the above problem, an embodiment of the present disclosure provides an array substrate comprising a display driving area and a non-display driving area, wherein the array substrate comprises: a substrate, a buffer layer disposed on the substrate, a first active layer disposed at a side of the buffer layer away from the buffer layer, a semiconductor insulation layer disposed on the first active layer in the display driving area, a second active layer disposed on the semiconductor insulation layer in the display driving area, a gate insulation layer disposed on the first active layer, the substrate and the second active layer, a gate disposed on the gate insulation layer, an interlayer insulation layer disposed on the gate and the gate insulation layer, and a source/drain metal layer disposed on the interlayer insulation layer. Wherein in the display driving area, the source/drain metal layer is connected to the second active layer by a first through hole, and in the non-display driving area, the source/drain metal layer is connected to the first active layer by a second through hole.

In an embodiment, the first through hole extends through the interlayer insulation layer and a part of the gate insulation layer until reaching the second active layer.

In an embodiment, the second through hole extends through the interlayer insulation layer and a part of the gate insulation layer until reaching the first active layer.

In an embodiment, a material of the first active layer is low temperature poly-silicon.

In an embodiment, a material of the second active layer is indium gallium zinc oxide.

In an embodiment, a material of the buffer layer comprises silicon nitride and silicon oxide.

In an embodiment, the source/drain metal layer comprises a source line and a drain line.

In an embodiment, in the display driving area, the source line and the drain line are connected to the second active layer, and in the non-display driving area, the source line and the drain line are connected to the first active layer.

An embodiment of the present disclosure provides a method for manufacturing an array substrate comprising: providing a substrate comprising a display driving area and a non-display driving area, depositing a buffer layer and an amorphous silicon layer in sequence on the substrate, forming a first active layer by laser annealing of the amorphous silicon layer, depositing a semiconductor insulation layer and a second active layer on the first active layer in the display driving area, forming a photoresist layer on the first active layer and the second active layer, and forming a patterned layer by exposing and developing the photoresist layer, etching the first active layer, the semiconductor insulation layer, and the second active layer to form corresponding patterns, and removing the patterned layer, forming a gate insulation layer on the substrate, the first active layer, and the second active layer, and depositing a gate, an interlayer insulation layer, and a source/drain metal layer on the gate insulation layer in sequence.

In an embodiment, in the step of etching the first active layer, the semiconductor insulation layer, and the second active layer to form corresponding patterns, in the display driving area a process of the etching is a wet etching process, and in the non-display driving area a process of the etching is a dry etching process.

The embodiments of the present disclosure provide the array substrate and the method for manufacturing the same. By disposing hybrid TFT on the substrate which comprises disposing an oxide TFT in the display driving area and disposing an LTPS TFT in the non-display driving area, not only can a driving current of an LCD gate driving circuit be improved, but a leakage current can also be diminished when LCD display pixels are driven. When manufacturing the hybrid TFT structure, the second active layer in the display driving area is disposed on the first active layer, and the semiconductor insulation layer is disposed between the first active layer and the second active layer, so that patterns of the first active layer and the second active layer can be formed by etching through one mask during an etching process, thus reducing manufacturing cost.

### BRIEF DESCRIPTION OF DRAWINGS

To describe the technical solutions of the embodiments of the present disclosure more clearly, the following briefly introduces the accompanying drawings used in the description of the embodiments of the present disclosure. Apparently, the accompanying drawings described below illustrate only some exemplary embodiments of the present disclosure, and persons skilled in the art may derive other drawings from the drawings without making creative efforts.

FIG. 1 is a schematic structural diagram illustrating a hybrid TFT with a top gate structure in prior art.

FIG. 2 is a schematic structural diagram illustrating a hybrid TFT with a bottom gate structure in prior art.

FIG. 3 is a schematic structural diagram illustrating an array substrate according to an embodiment of the present disclosure.

FIG. 4 is a schematic structural diagram illustrating an array substrate according to an embodiment of the present disclosure.

FIG. 5 is a schematic structural diagram illustrating a photoresist layer according to an embodiment of the present disclosure.

FIG. 6 is a schematic structural diagram illustrating a patterned layer according to an embodiment of the present disclosure.

FIG. 7 is a schematic structural diagram illustrating a first active layer, a semiconductor insulation layer, and a second active layer after etching according to an embodiment of the present disclosure.

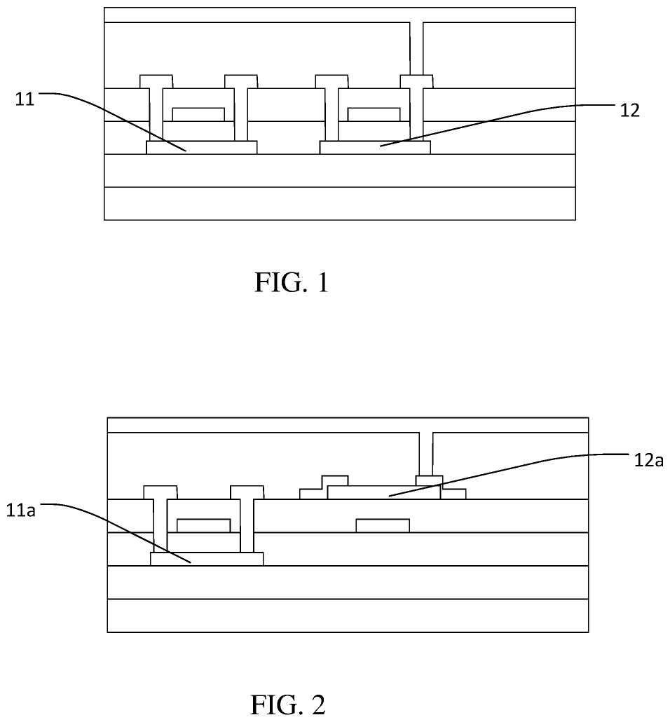

A part of component identifications is shown as follows: array substrate 100, display driving area 120, non-display driving area 110, substrate 101, buffer layer 102, first active layer 107, semiconductor insulation layer 108, second active layer 109, gate insulation layer 103, gate 1010, interlayer insulation layer 104, source/drain metal layer 1011, planarization layer 105, transparent electrode 106, photoresist layer 1012, patterned layer 1013, first through hole 1014, and second through hole 1015.

### DETAILED DESCRIPTION OF PREFERRED EMBODIMENTS

The following description of every embodiment with reference to the accompanying drawings is used to exemplify a specific embodiment which may be carried out in the present disclosure. Directional terms mentioned in the present disclosure, such as “top”, “bottom”, “front”, “back”, “left”, “right”, “inside”, “outside”, “side” etc., are only used with reference to the orientation of the accompanying drawings. The component terms mentioned in the invention, such as first and second, are only used to distinguish different components, which can be better expressed. In the accompanying drawings, same reference numbers represent similar elements.

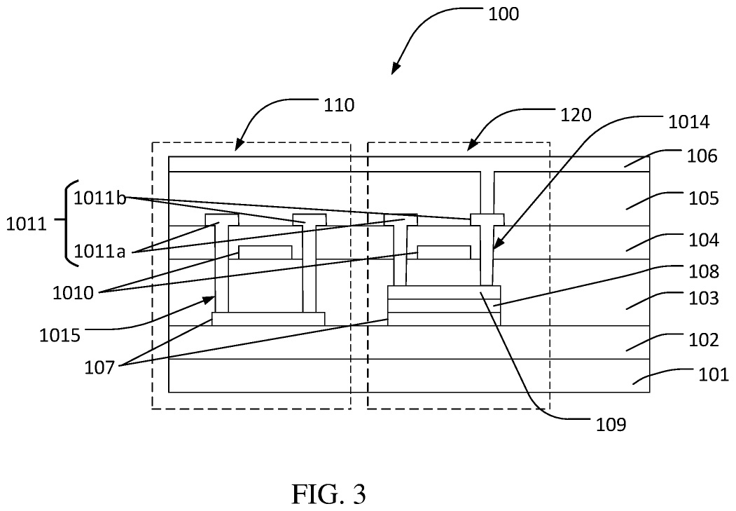

As shown in FIG. 3, in an embodiment of the present disclosure, an array substrate 100 is provided and comprises a display driving area 120 and a non-display driving area 110. The display driving area 120 is used to drive a display panel to display.

Further referring to FIG. 3, the array substrate 100 comprises a substrate 101, a buffer layer 102, a first active layer 107, a semiconductor insulation layer 108, a second active layer 109, a gate insulation layer 103, a gate 1010, an interlayer insulation layer 104, a source/drain metal layer 1011, a planarization layer 105, and a transparent electrode 106.

The buffer layer 102 is disposed on the substrate 101. A material of the buffer layer 102 comprises silicon nitride and silicon oxide.

The first active layer 107 is disposed at a side of the buffer layer 102 away from the substrate 101. A material of the first active layer 107 is low temperature poly-silicon.

The first active layer 107 has advantages of high mobility, small size, fast charging, and fast switching speed, and can be used to drive a gate 1010 of a TFT, having a good effect.

The semiconductor insulation layer 108 is disposed on the first active layer 107 in the display driving area 120.

The second active layer 109 is disposed on the semiconductor insulation layer 108 in the display driving area 120. A material of the second active layer 109 is indium gallium zinc oxide.

The second active layer 109 has advantages of good uniformity and low leakage current, and can be used to drive display pixels.

The gate insulation layer 103 is disposed on the first active layer 107, the substrate 101, and the second active layer 109. The gate 1010 is disposed on the gate insulation layer 103. The interlayer insulation layer 104 is disposed on the gate 1010 and the gate insulation layer 103. And the source/drain metal layer 1011 is disposed on the interlayer insulation layer 104.

In the display driving area 120, the source/drain metal layer 1011 is connected to the second active layer 109 by a first through hole 1014. The first through hole 1014 extends through the interlayer insulation layer 104 and a part of the gate insulation layer 103 until reaching the second active layer 109.

In the non-display driving area 110, the source/drain metal layer 1011 is connected to the first active layer 107 by a second through hole 1015.

The second through hole 1015 extends through the interlayer insulation layer 104 and a part of the gate insulation layer 103 until reaching the first active layer 107.

The source/drain metal layer 1011 comprises a source line 1011a and a drain line 1011b.

In the display driving area 120, the source line 1011a and the drain line 1011b are connected to the second active layer 109, and in the non-display driving area 110, the source line 1011a and the drain line 1011b are connected to the first active layer 107.

The planarization layer 105 is disposed on the source/drain metal layer 1011 and the interlayer insulation layer 104. A first electrode is disposed on the planarization layer 105 and connected to the source/drain metal layer 1011 in the display driving area 120.

An embodiment of the present disclosure also provides a method for manufacturing an array substrate 100 comprising steps S1 to S8.

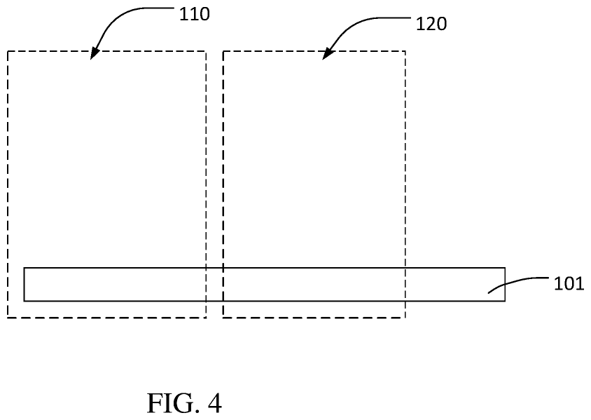

Step S1: as shown in FIG. 4, providing a substrate 101 comprising a display driving area 120 and a non-display driving area 110.

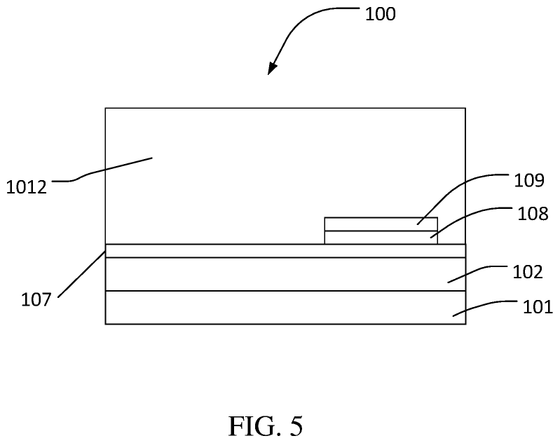

Step S2: as shown in FIG. 5, depositing a buffer layer 102 and an amorphous silicon layer in sequence on the substrate 101, wherein a material of the buffer layer 102 comprises silicon nitride and silicon oxide.

Step S3: forming a first active layer 107 by laser annealing of the amorphous silicon layer. The first active layer 107 has advantages of high mobility, small size, fast charging, and fast switching speed, and can be used to drive a gate 1010 of a TFT, having a good effect.

Step S4: depositing a semiconductor insulation layer 108 and a second active layer 109 on the first active layer 107 in the display driving area 120.

Step S5: forming a photoresist layer 1012 on the first active layer 107 and the second active layer 109, and forming a patterned layer 1013 by exposing and developing the photoresist layer 1012. A shape of the patterned layer 1013 is shown in FIG. 5. The patterned layer 1013 between the display driving area 120 and the non-display driving area 110 is removed to form the formed patterned layer 1013 by which the active layer in the display driving area 120 and the non-display driving area 110 is etched.

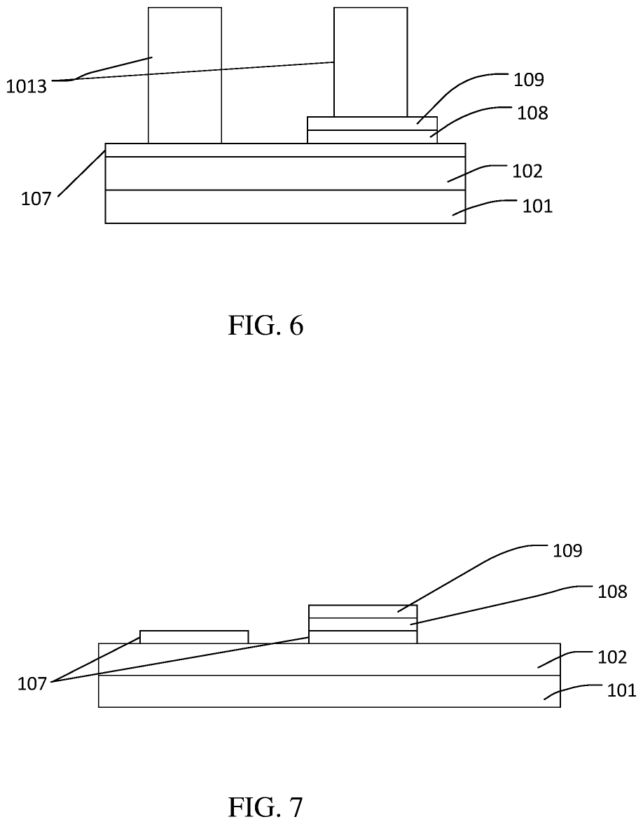

Step S6: as shown in FIG. 6, etching the first active layer 107, the semiconductor insulation layer 108, and the second active layer 109 to form corresponding patterns. Wherein, an area not covered by the photoresist layer is etched and only an area covered by the photoresist layer is retained.

In the step of etching the first active layer 107, the semiconductor insulation layer 108, and the second active layer 109 to form corresponding patterns, in the display driving area 120 a process of etching is a wet etching process, and in the non-display driving area 110 a process of etching is a dry etching process.

Wet etching utilizes liquid chemical reagents to remove materials on a surface of the second active layer 109 in a chemical way. Dry etching is a process of exposing a surface of the first active layer 107 to the plasma generated in the air, and the plasma passes through a gap in the pattern layer 1013 and reacts physically or chemically with the second active layer 109 to remove the exposed surface material. Furthermore, dry etching can make the second active layer 109 form a complete pattern.

Step S7: forming a gate insulation layer 103 on the substrate 101, the first active layer 107, and the second active layer 109.

Step S8: depositing a gate 1010, an interlayer insulation layer 104, and a source/drain metal layer 1011 on the gate insulation layer 103 in sequence.

In the display driving area 120, the source/drain metal layer 1011 is connected to the second active layer 109 by a first through hole 1014. The first through hole 1014 extends through the interlayer insulation layer 104 and a part of the gate insulation layer 103 until reaching the second active layer 109.

In the non-display driving area 110, the source/drain metal layer 1011 is connected to the first active layer 107 by a second through hole 1015.

The second through hole 1015 extends through the interlayer insulation layer 104 and a part of the gate insulation layer 103 until reaching the first active layer 107.

The source/drain metal layer 1011 comprises a source line and a drain line.

In the display driving area 120, the source line and the drain line are connected to the second active layer 109, and in the non-display driving area 110, the source line and the drain line are connected to the first active layer 107.

The embodiments of the present disclosure provide the array substrate and the method for manufacturing the same. By disposing the hybrid TFT on the substrate 101 which comprises disposing an oxide TFT in the display driving area 120 and disposing an LTPS TFT in the non-display driving area 110, not only can a driving current of an LCD gate driving circuit be improved, but a leakage current can also be diminished when LCD display pixels are driven. When manufacturing the hybrid TFT structure, the second active layer 109 in the display driving area 120 is disposed on the first active layer 107, and the semiconductor insulation layer 108 is disposed between the first active layer and the second active layer, so that patterns of the first active layer 107 and the second active layer 109 can be formed by etching through one mask during an etching process, thus reducing manufacturing cost.

The technical scope of the present disclosure is not limited to the contents stated in the description. Various modifications and changes may be made by ordinary person skilled in the art without departing from the technical spirit of this disclosure. And the modifications and changes are subject to the protecting scope of the disclosure.

What is claimed is:

1. An array substrate comprising a display driving area and a non-display driving area, wherein the array substrate comprises:
a substrate;
a buffer layer disposed on the substrate;
a first active layer disposed at a side of the buffer layer away from the buffer layer;
a semiconductor insulation layer disposed on the first active layer in the display driving area;
a second active layer disposed on the semiconductor insulation layer in the display driving area;
a gate insulation layer disposed on the first active layer, the substrate, and the second active layer;
a gate disposed on the gate insulation layer;
an interlayer insulation layer disposed on the gate and the gate insulation layer; and
a source/drain metal layer disposed on the interlayer insulation layer;
wherein in the display driving area, the source/drain metal layer is connected to the second active layer by a first through hole, and in the non-display driving area, the source/drain metal layer is connected to the first active layer by a second through hole.

2. The array substrate as claimed in claim 1, wherein the first through hole extends through the interlayer insulation layer and a part of the gate insulation layer until reaching the second active layer.

3. The array substrate as claimed in claim 1, wherein the second through hole extends through the interlayer insulation layer and a part of the gate insulation layer until reaching the first active layer.

4. The array substrate as claimed in claim 1, wherein a material of the first active layer is low temperature poly-silicon.

5. The array substrate as claimed in claim 1, wherein a material of the second active layer is indium gallium zinc oxide.

6. The array substrate as claimed in claim 1, wherein a material of the buffer layer comprises silicon nitride and silicon oxide.

7. The array substrate as claimed in claim 1, wherein the source/drain metal layer comprises a source line and a drain line.

8. The array substrate as claimed in claim 7, wherein in the display driving area, the source line and the drain line are connected to the second active layer, and in the non-display driving area, the source line and the drain line are connected to the first active layer.

9. A method for manufacturing an array substrate, comprising following steps:
providing a substrate comprising a display driving area and a non-display driving area;
depositing a buffer layer and an amorphous silicon layer in sequence on the substrate;
forming a first active layer by laser annealing of the amorphous silicon layer;
depositing a semiconductor insulation layer and a second active layer on the first active layer in the display driving area;
forming a photoresist layer on the first active layer and the second active layer, and forming a patterned layer by exposing and developing the photoresist layer;
etching the first active layer, the semiconductor insulation layer, and the second active layer to form corresponding patterns, and removing the patterned layer;
forming a gate insulation layer on the substrate, the first active layer, and the second active layer; and
depositing a gate, an interlayer insulation layer, and a source/drain metal layer on the gate insulation layer in sequence.

10. The method for manufacturing the array substrate as claimed in claim 9, wherein in the step of etching the first active layer, the semiconductor insulation layer, and the second active layer to form corresponding patterns, a process of etching is a wet etching process in the display driving area, and a process of etching is a dry etching process in the non-display driving area.
